(19) United States
(12) Patent Application Publication
(10) Pub. No.: US 2018/0258527 A1
(43) Pub. Date: Sep. 13, 2018

(54) Film Forming Apparatus

(71) Applicant: TOKYO ELECTRON LIMITED, Tokyo (JP)

(72) Inventors: Yu SASAKI, Iwate (JP); Kosuke TAKAHASHI, Iwate (JP); Fumiaki HAYASE, Iwate (JP)

(21) Appl. No.: 15/914,261

(22) Filed: Mar. 7, 2018

(30) Foreign Application Priority Data
Mar. 10, 2017 (JP) 2017-046479

(51) Int. Cl. C23C 16/458; C23C 16/455; C23C 16/46; C23C 16/52

(52) U.S. Cl. CPC C23C 16/4584; C23C 16/45578; C23C 16/52; C23C 16/46; C23C 16/45544

(57) ABSTRACT

A film forming apparatus includes first and second processing gas supply parts for respectively supplying first and second processing gases to the substrate, and a separation region formed between first and second processing regions to separate an atmosphere of the first processing region to which the first processing gas is supplied and an atmosphere of the second processing region to which the second processing gas is supplied. The separation region includes: a separation region forming member including edge portions radially extending from a rotation center to a peripheral edge of a rotary table and for forming a narrow space between the edge portions and the rotary table, and a concave portion provided in a region sandwiched between adjacent edge portions and for forming a buffer space; and a separation gas supply part for supplying a separation gas into the buffer space.

### CROSS-REFERENCE TO RELATED APPLICATION

This application is based upon and claims the benefit of priority from Japanese Patent Application No. 2017-046479, filed on Mar. 10, 2017, the entire contents of which are incorporated herein by reference.

### TECHNICAL FIELD

The present disclosure relates to a technique for forming a film by supplying different processing gases to first and second processing regions separated from each other and defined above a rotary table on which a substrate is mounted.

### BACKGROUND

As a film forming apparatus for forming a film on a semiconductor wafer (hereinafter referred to as “wafer”) which is a substrate, a film forming apparatus has been used in which a plurality of wafers are mounted on a rotary table arranged inside a vacuum container so as to surround the rotation center of the rotary table, and a plurality of processing regions (first and second processing regions) are arranged separately so that different processing gases are supplied to predetermined positions defined above the rotary table. In this film forming apparatus, when the rotary table is rotated, each wafer revolves around the rotation center and repeatedly passes through the respective processing regions in order. The processing gases react on the surface of each wafer, whereby atomic layers or molecular layers are stacked one above another to form a film.

Regarding the film forming apparatus described above, the applicant of the present disclosure has developed a film forming apparatus in which a fan-shaped convex portion protruding downward from a top plate of a vacuum container is provided, a narrow space is formed between a rotary table and the convex portion, a groove portion extending along the radial direction of the rotary table is formed in the convex portion, and a separation gas nozzle having a plurality of discharge holes formed at intervals along the length direction of the nozzle is disposed in the groove portion. A separation gas is discharged from the separation gas nozzle toward the rotary table so that the separation gas flows through the above-mentioned narrow space and flows out into respective processing regions. The separation gas can separate the atmospheres in the adjacent processing regions and can suppress the mixing of the processing gases. With regard to the above-described film forming apparatus, the inventors of the present disclosure have been developing a technique for effectively separating the atmospheres of the processing regions.

### SUMMARY

Some embodiments of the present disclosure provide a film forming apparatus capable of effectively separating the atmospheres of first and second processing regions defined above a rotary table.

According to one embodiment of the present disclosure, there is provided a film forming apparatus for performing a film forming process by mounting a substrate on one surface side of a rotary table provided inside a vacuum container and supplying a processing gas to the substrate while revolving the substrate around a rotation center of the rotary table by rotating the rotary table, including: a first processing gas supply part and a second processing gas supply part provided apart from each other in a rotation direction of the rotary table and configured to supply a first processing gas and a second processing gas to the substrate, respectively; and a separation region formed between a first processing region and a second processing region to separate an atmosphere of the first processing region to which the first processing gas is supplied and an atmosphere of the second processing region to which the second processing gas is supplied, wherein the separation region includes: a separation region forming member including a plurality of edge portions extending in a radial direction from a rotation center to a peripheral edge of the rotary table, the plurality of edge portions being spaced apart from each other in the rotation direction, and configured to form a narrow space between the plurality of edge portions and the rotary table, and a concave portion provided in a region sandwiched between the plurality of edge portions disposed adjacent to each other, the concave portion being opened toward one surface side of the rotary table, and configured to form a buffer space having a larger height dimension than the narrow space between the concave portion and the rotary table; and a separation gas supply part configured to supply a separation gas into the buffer space.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical sectional side view of a film forming apparatus according to an embodiment of the present disclosure.

FIG. 2 is a horizontal sectional plan view of the film forming apparatus.

FIG. 3 is a plan view of a separation region forming member provided in the film forming apparatus as viewed from the lower surface side.

FIG. 4 is an operation diagram of the film forming apparatus.

FIG. 5 is a vertical sectional development view showing first and second processing regions and a separation region provided in the film forming apparatus.

FIG. 6 is a plan view showing a modification of the separation region forming member.

FIG. 7 is a plan view showing another modification of the separation region forming member.

FIGS. 8A and 8B are explanatory views showing a configuration of a separation region forming member according to a comparative example.

FIG. 9 is an explanatory diagram showing a simulation result according to an example.

FIG. 10 is an explanatory diagram showing a simulation result according to a comparative example.

FIG. 11 is a first explanatory view showing a film formation result according to an example.

FIG. 12 is a second explanatory view showing a film formation result according to an example.

FIG. 13 is a first explanatory view showing a film formation result according to a comparative example.

FIG. 14 is a second explanatory view showing a film formation result according to a comparative example.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

A film forming apparatus 1 for forming a ZrO film on a wafer W as a substrate by an ALD (Atomic Layer Deposition) method will be described as an embodiment of the present disclosure. An outline of the ALD method performed in the film forming apparatus 1 of this embodiment will now be described. A raw material gas (first processing gas) containing Zr (zirconium), for example, a gas obtained by vaporizing tri (dimethylamino) cyclopentadienyl zirconium (hereinafter referred to as “ZAC”), is adsorbed onto a wafer W. Thereafter, an ozone (O₃) gas which is an oxidizing gas (second processing gas) for oxidizing the ZAC is supplied to the surface of the wafer W to form a molecular layer of ZrO (zirconium oxide). By repeating a series of processes on one sheet of wafer W a plurality of times, a ZrO film is formed.

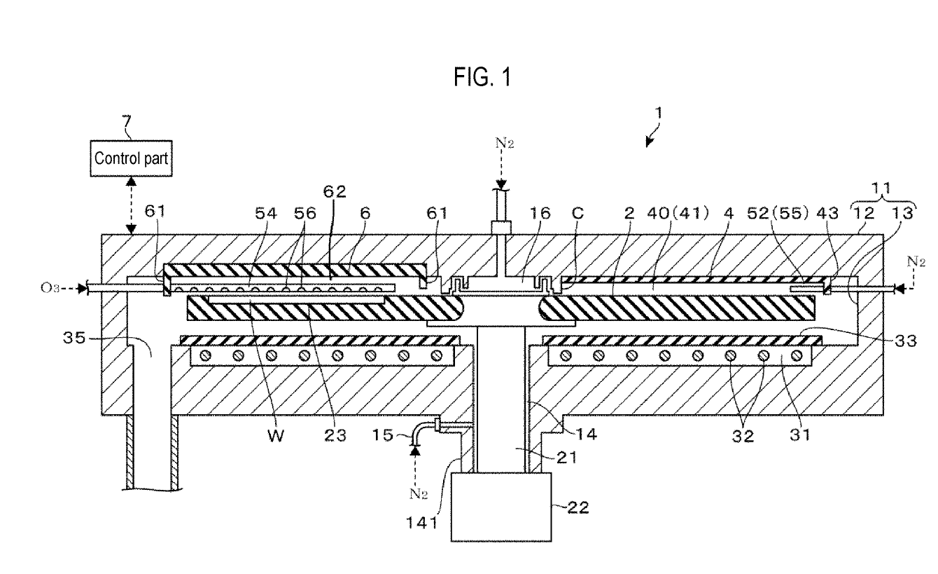

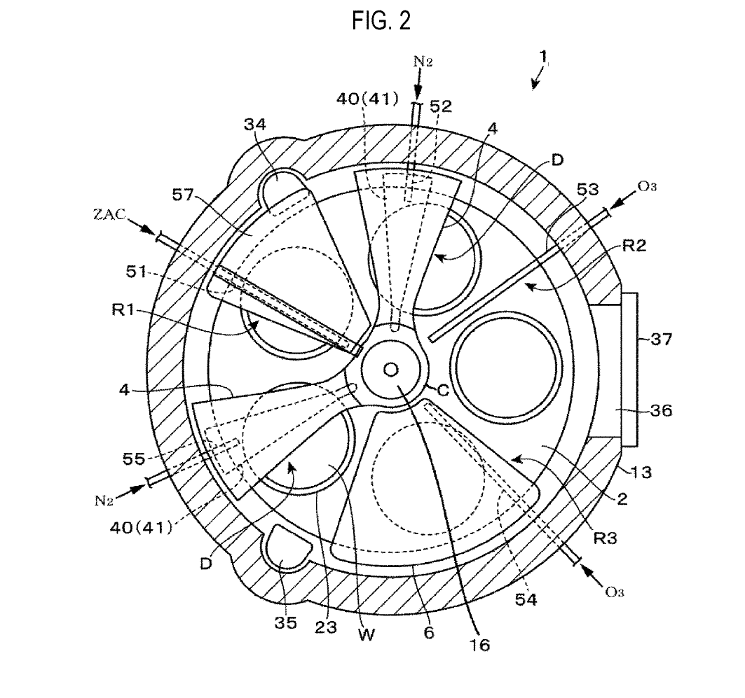

As shown in FIGS. 1 and 2, the film forming apparatus 1 includes a substantially circular flat vacuum container 11 and a disk-shaped rotary table 2 provided inside the vacuum container 11. The vacuum container 11 is composed of a top plate 12 and a container body 13 which forms a side wall and a bottom portion of the vacuum container 11.

The rotary table 2 is made of, for example, quartz glass (hereinafter simply referred to as “quartz”). A metal-made rotary shaft 21 extending vertically downward is provided at the central portion of the rotary table 2. The rotary shaft 21 is inserted into a sleeve 141 having an opening 14 formed in the bottom portion of the container body 13. A rotational drive part 22 provided so as to airtightly close the vacuum container 11 is connected to the lower end portion of the sleeve 141. The rotary table 2 may be made of metal such as stainless steel or the like.

The rotary table 2 is supported horizontally inside the vacuum container 11 via the rotary shaft 21 and is rotated, for example, clockwise as viewed from the upper surface side, by the action of the rotational drive part 22. In order to prevent the raw material gas, the oxidizing gas, or the like from flowing around from the upper surface side to the lower surface side of the rotary table 2, a gas supply pipe 15 for supplying an N₂ (nitrogen) gas to the gap between the opening 14 of the sleeve 141 and the container body 13 and the rotary shaft 21 is provided in the upper end portion of the sleeve 141.

On the lower surface of the top plate 12 constituting the vacuum container 11, a central region C is formed which protrudes so as to face the central portion of the rotary table 2 and has an annular plan-view shape. Furthermore, on the lower surface of the top plate 12, a separation region forming member 4 is provided which extends from the central region C toward the outside of the rotary table 2 and has a fan-shaped plan-view shape. The detailed configuration of the separation region forming member 4 will be described later.

The gap between the central region C and the central portion of the rotary table 2 constitutes a flow path 16 of an N₂ gas. The N₂ gas is supplied to the flow path 16 from a gas supply pipe connected to the top plate 12. The N₂ flowing into the flow path 16 is discharged from the gap between the upper surface of the rotary table 2 and the central region C toward the radially outer side of the rotary table 2 over the entire circumference thereof. The N₂ gas prevents a raw material gas and an oxidizing gas supplied to different positions (an adsorption region (first processing region) R1 and first and second oxidizing regions (second processing regions) R2 and R3 to be described later) on the rotary table 2 from bypassing the central portion (flow path 16) of the rotary table 2 and making contact with each other.

As shown in FIG. 1, a flat concave portion 31 having an annular plan-view shape is formed in the bottom surface of the container body 13 positioned below the rotary table 2 along the circumferential direction of the rotary table 2. A heater 32 formed of, for example, an elongated tubular carbon wire heater is disposed on the bottom surface of the concave portion 31 over a region facing the entire lower surface of the rotary table 2. The heater 32 generates heat based on electric power supplied from a power supply part (not shown). The heater 32 heats the wafer W via the rotary table 2. In addition, the upper surface of the concave portion 31 in which the heater 32 is disposed is closed by a shield 33 which is an annular plate member made of, for example, quartz.

Exhaust ports 34 and 35 for evacuating the interior of the vacuum container 11 are opened in the bottom surface of the container body 13 located on the outer peripheral side of the concave portion 31. A vacuum exhaust mechanism (not shown) constituted by a vacuum pump or the like is connected to the exhaust ports 34 and 35.

As shown in FIG. 2, a loading/unloading port 36 and a gate valve 37 are located in the side wall of the container body 13. The wafer W is transferred through the loading/unloading port 36, and the gate valve 37 opens and closes the loading/unloading port 36. The wafer W held by an external transfer mechanism is loaded into the vacuum container 11 via the loading/unloading port 36. A plurality of recesses 23 are located on the upper surface of the rotary table 2, and surround the flow path 16 corresponding to the rotation center of the rotary table 2 as mounting regions of the wafers W. The wafers W loaded into the vacuum container 11 are mounted in the respective recesses 23. The delivery of the wafer W between the transfer mechanism and the recess is performed by lift pins which are vertically movable between an upper position and a lower position of the rotary table 2 via through-holes (not shown) formed in each recess 23. A description of the lift pins is omitted.

As shown in FIG. 2, above the rotary table 2, a material gas nozzle 51, a separation gas nozzle 52, a first oxidizing gas nozzle 53, a second oxidizing gas nozzle 54 and a separation gas nozzle 55 are arranged in the named order at intervals along the rotation direction of the rotary table 2. Among these gas nozzles 51 to 55, the raw material gas nozzle 51 and the first and second oxidizing gas nozzles 53 and 54 are formed in a rod shape to horizontally extend along the radial direction from the side wall of the vacuum container 11 toward the central portion of the rotary table 2. In the lower surface of a nozzle body constituting each gas nozzle 51, 53 or 54, a large number of discharge holes 56 are formed at intervals from each other. A ZAC gas and an ozone gas supplied from a raw material gas supply source (not shown) or an oxidizing gas supply source (not shown) are discharged downward through the discharge holes 56. In this embodiment, the raw material gas nozzle 51 constitutes a first processing gas supply part, and the first and second oxidizing gas nozzles 53 and 54 constitute a second processing gas supply part.

The configuration of the separation gas nozzles 52 and 55 will be described together with the configuration of the separation region forming member 4 described later. In the following description, the side located away from a predetermined reference position along the rotation direction of the rotary table 2 will be referred to as a downstream side in the rotation direction, and the opposite side will be referred to as an upstream side.

As shown in FIG. 2, the raw material gas nozzle 51 is covered with a quartz-made nozzle cover 57 which is formed in a fan-like shape to extend from the raw material gas nozzle 51 toward the upstream side and the downstream side in the rotation direction of the rotary table 2. The nozzle cover 57 has a role of increasing the concentration of the ZAC gas under the nozzle cover 57 and enhancing the adsorption of the ZAC gas onto the wafer W.

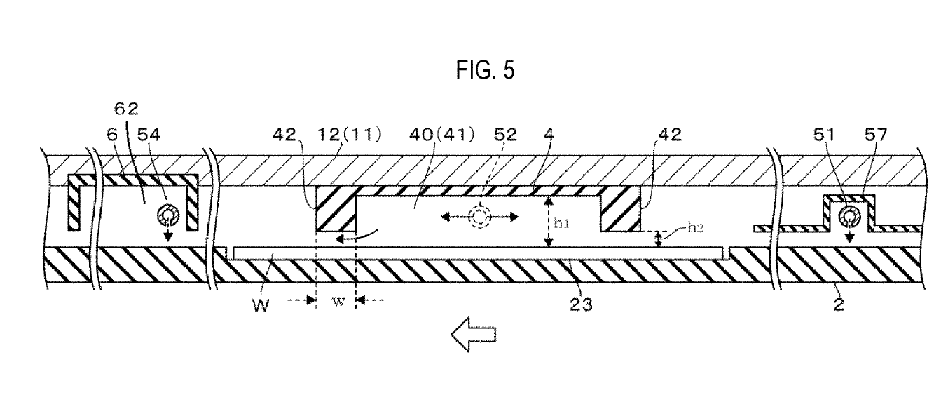

In addition, the first oxidizing gas nozzle 53 and the second oxidizing gas nozzle 54 are spaced apart from each other in the rotation direction of the rotary table 2. The second oxidizing gas nozzle 54 existing on the downstream side is covered with a quartz-made oxidizing region cover 6 which is formed in a fan-like shape to extend from the arrangement position of the second oxidizing gas nozzle 54 toward the downstream side. As shown in FIGS. 1 and 5, a concave portion 62 is formed in the lower surface of the oxidizing region cover 6. The second oxidizing gas nozzle 54 is inserted into the concave portion 62 at an upstream side position.

The peripheral edge portion 61 of the oxidizing region cover 6 surrounding the concave portion 62 protrudes more downward than the ceiling surface of the concave portion 62 and forms a narrow gap with the upper surface of the rotary table 2. The ozone gas supplied from the second oxidizing gas nozzle 54 spreads in the space between the oxidizing region cover 6 and the rotary table 2 and then flows out outside of the oxidizing region cover 6. The oxidizing region cover 6 has a role of increasing the concentration of the ozone gas in the space and enhancing the reactivity with the ZAC gas adsorbed onto the wafer W.

As shown in FIG. 2, an absorption region R1 and a first oxidizing region R2 are located above the rotary table 2. The absorption region R1 is located below the nozzle cover 57 of the raw material gas nozzle 51 to adsorb a raw material gas such as ZAC gas. The ZAC gas is adsorbed by the ozone gas in the first oxidizing region R2 located below the first oxidizing gas nozzle 53. In this embodiment in which the oxidizing region cover 6 is provided, the space between the oxidizing region cover 6 and the rotary table 2 serves as the second oxidizing region R3. In the present embodiment, the adsorption region R1 corresponds to a first processing region, and the first and second oxidizing regions R2 and R3 correspond to a second processing region.

In the film forming apparatus 1 of this embodiment that can supply the ozone gas using the first and second oxidizing gas nozzles 53 and 54, film formation may be performed using both oxidizing gas nozzles 53 and 54 or may be performed using one of the oxidizing gas nozzles 53 and 54, depending on the film forming conditions and the like.

When viewed in the rotation direction of the rotary table 2, the separation region forming members 4 are disposed between the adsorption region R1 and the first oxidizing region R2 and between the second oxidizing region R3 and the adsorption region R1. The separation region forming members 4 play a role of separating the adsorption region R1 and the first and second oxidizing regions R2 and R3 from each other to form separation regions D for preventing the mixing of the raw material gas and the oxidizing gas.

One exhaust port 34 formed in the bottom surface of the container body 13 is opened outward of the rotary table 2 at a position in the vicinity of the downstream end of the nozzle cover 57 (the adsorption region R1) and is configured to exhaust a surplus ZAC gas. The other exhaust port 35 is opened outward of the rotary table 2 at a position between the second oxidizing region R3 and the separation region D adjacent to the second oxidizing region R3 at the downstream side in the rotation direction and is configured to exhaust a surplus ozone gas. The N₂ gas respectively supplied from the respective separation regions D, the gas supply pipe 15 below the rotary table 2 and the central region C of the rotary table 2 is also exhausted from the respective exhaust ports 34 and 35.

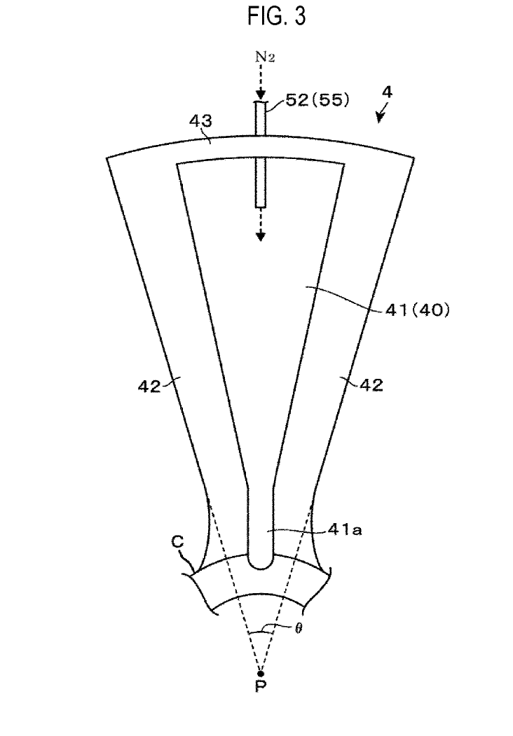

In the film forming apparatus 1 configured as above, each of the separation regions D is formed by the separation region forming member 4 having a configuration different from the conventional configuration. Hereinafter, the configurations of the separation region forming member 4 and the separation region D will be described with reference to FIG. 3.

The separation region forming member 4 of this example is made of, for example, quartz, and is a flat member having a substantially fan-like plan-view shape. As shown in FIG. 3, the separation region forming member 4 is formed such that, when viewed from a point P which is the rotation center of the rotary table 2, the center angle θ defined by two sides (edge portions 42) extending in a substantially radial direction falls within a range of 20 degrees or more and 60 degrees or less, specifically a range of 20 degrees or more and 30 degrees or less. In this example, there is illustrated a case where the separation region forming member 4 made of quartz is adopted from the viewpoint of prevention of metal contamination. However, in the film forming apparatus 1 capable of adopting the separation region forming member 4 made of metal having higher strength than quartz, the lower limit of the center angle θ may be reduced to about 10 degrees.

A substantially fan-shaped concave portion 41 is formed on the lower surface of the separation region forming member 4 and has a center angle smaller than that of the main body of the separation region forming member 4. The concave portion 41 is opened downward. In a region close to the center of the fan shape, the concave portion 41 forms a groove region 41a having a constant width and extends up to the above-described central region C. The periphery (the two sides extending in the radial direction and the circular arc extending in the circumferential direction) of the concave portion 41 is defined by edge portions 42 and 43 protruding so as to surround the concave portion 41.

FIG. 5 shows a state in which the vacuum container 11 is developed from the side surface side. As shown in FIGS. 1 and 5, the separation region forming member 4 is fixed to the lower surface side of the top plate 12 constituting the vacuum container 11 and is configured to define the above-described separation region D. At each arrangement position of the separation region forming member 4A, a narrow gap is formed between the lower surfaces of the two edge portions 42 extending in the radial direction and the upper surface of the rotary table 2 (FIG. 5). Since the length of the edge portions 42 in the radial direction is larger than the radius of the rotary table 2, the edge portion 43 in the circumferential direction is disposed outside the outer periphery of the rotary table 2. Accordingly, a gap is also formed between the outer periphery of the rotary table 2 and the inner periphery of the edge portion 43 in the circumferential direction (FIGS. 1 and 2).

With the configuration described above, as shown in FIGS. 1 and 5, a buffer space 40 is provided in a region between the adjacent edge portions 42, opened toward the upper surface (one surface side) of the rotary table 2 on which the wafer W is mounted, and configured to have a larger height dimension than the small space between the lower surfaces of the edge portions 42 and the upper surface of the rotary table 2. The buffer space 40 is formed between the concave portion 41 of each separation region forming member 4 and the upper surface of the rotary table 2.

As shown in FIGS. 1 and 3, the separation gas nozzle 52 or 55 is inserted into the buffer space 40 from the side wall of the vacuum container 11 (the container body 13) through the edge portion 43. The separation gas nozzle 52 or 55 extends into the buffer space 40 along the radial direction of the rotary table 2. The separation gas nozzle 52 or 55 is configured to discharge an inert gas, for example, an N₂ gas, which is a separation gas supplied from a separation gas supply source (not shown), into the buffer space 40. An opening is formed in the distal end portion of the separation gas nozzle 52 or 55 inserted into the buffer space 40. The separation gas is introduced from the opening into the buffer space 40, for example, in the lateral direction along the radial direction. The separation gas nozzles 52 and 55 constitute a separation gas supply part of the present embodiment.

Now, an example of design variables related to the buffer space 40 will be described with reference to FIG. 5. For example, in the case of the film forming apparatus 1 in which five to six wafers W having a diameter of 300 mm are mounted on the rotary table 2 having a radius of 400 to 600 mm to perform a film forming process, the height dimension h₁ from the upper surface of the rotary table 2 (the upper surface of the wafer W mounted inside the recess 23, which holds true in the following description) to the ceiling surface of the buffer space 40 is set a value within a range of 17 to 20 mm. In addition, the height dimension h₂ of the small gap between the edge portions 42 in the radial direction and the upper surface of the rotary table 2 is set to a value within a range of 1 to 4 mm. In addition, the width dimension w of the edge portions 42 in the radial direction located at both ends of the fan shape is set to a value within a range of 50 to 60 mm. In addition, the width dimension of the groove region 41a where the width of the buffer space 40 becomes narrow may be 20 mm or more.

In the buffer space 40 having the dimension ranges described above by way of example, the distal end of the separation gas nozzle 52 or 55 having a length within a range of 85 to 150 mm is disposed via the circumferential edge portion 43 so as to be positioned inside the buffer space 40.

As shown in FIG. 1, the film forming apparatus 1 configured as above is provided with a control part 7 formed of a computer for controlling the operation of the entire apparatus. In the control part 7, there is stored a program for executing a film forming process on the wafer W. The program transmits a control signal to each part of the film forming apparatus 1 to control the operation of each part. Specifically, the adjustment of the supply amounts of various gases supplied from the gas nozzles 51 to 55, the output control of the heater 32, the adjustment of the supply amount of the N₂ gas supplied from the gas supply pipe 15 and the flow path 16 of the central region C, the adjustment of the rotation speed of the rotary table 2 rotated by the rotational drive part 22, and the like are performed in accordance with the control signal. In the program, a group of steps is incorporated so as to perform the above control so that the above-described operations are executed. The program is installed on the control part 7 from a storage medium such as a hard disk, a compact disk, a magneto-optical disk, a memory card, a flexible disk or the like.

The operation of the film forming apparatus having the above-described configuration will be described.

Initially, the film forming apparatus 1 adjusts an internal pressure of the vacuum container 11 and the output of the heater 32 to the state at the time of loading the wafer W, and waits for the loading of the wafer W. Then, for example, when the wafer W to be processed is transferred to the film forming apparatus 1 by a transfer mechanism (not shown) provided in the adjacent vacuum transfer chamber, the gate valve 37 is opened. The transfer mechanism enters the vacuum container 11 via the opened loading/unloading port 36, and mounts the wafer W into the recess 23 of the rotary table 2. Then, this operation is repeated while intermittently rotating the rotary table 2, so that the wafers W are mounted into the respective recesses 23.

Upon completion of the loading of the wafer W, the transfer mechanism is retracted from the inside of the vacuum container 11. The gate valve 37 is closed, and the interior of the vacuum container 11 is exhausted to have a predetermined pressure by the exhaust from the exhaust ports 34 and 35. A predetermined amount of N₂ gas is supplied from the separation gas nozzles 52 and 55, the flow path 16 in the central region C and the gas supply pipe 15 provided below the rotary table 2, respectively. Then, the rotation of the rotary table 2 is started. The rotation speed of the rotary table 2 is adjusted so as to achieve a predetermined rotation speed. Power supply from the power supply part to the heater 32 is started to heat the wafer W.

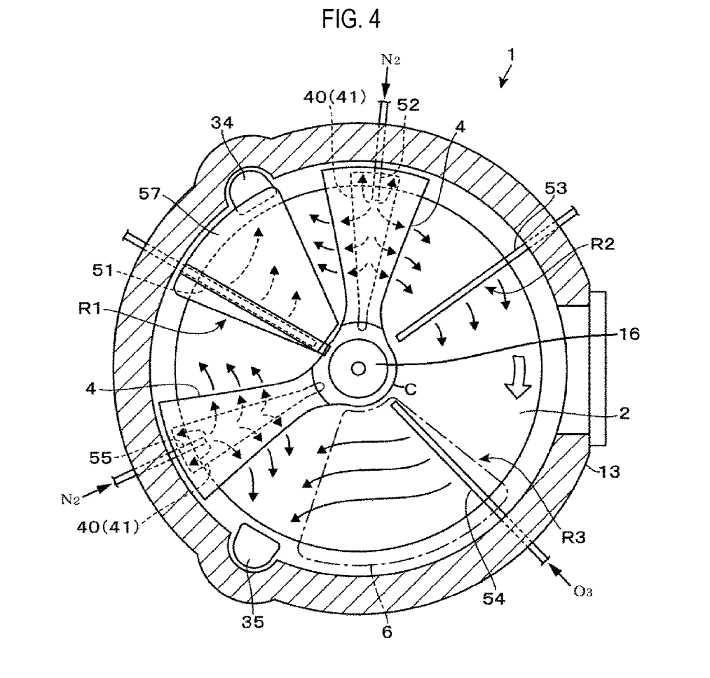

When the wafer W is heated to a set temperature, for example, 250 degrees C., the supply of various gases (a raw material and an oxidizing gas) from the raw material gas nozzle 51 and the first and second oxidizing gas nozzles 53 and 54 is started (FIG. 4). Regarding the two first and second oxidizing gas nozzles 53 and 54, whether the oxidizing gas is to be supplied by using one of them or by using both of them is set in advance in a process recipe in which the conditions of a film forming process are stored.

As the raw material gas and the oxidizing gas are supplied, the wafer W mounted in each recess 23 of the rotary table 2 repeatedly passes through the adsorption region R1 defined below the nozzle cover 57 for the raw material gas nozzle 51, the first oxidizing region R2 defined below the first oxidizing gas nozzle 53, and the second oxidizing region R3 covered with the oxidizing region cover 6, in the named order.

In the adsorption region R1, the ZAC gas discharged from the raw material gas nozzle 51 is adsorbed onto the wafer W. In the first and second oxidizing regions R2 and R3, the ZAC thus adsorbed is oxidized by the ozone gas supplied from the oxidizing gas nozzle 53, whereby one or more molecular layers of ZrO are formed.

As the rotation of the rotary table 2 is continued in this way, the molecular layers of ZrO are sequentially laminated on the surface of the wafer W. Thus, a ZrO film is formed and the film thickness thereof gradually increases. At this time, the adsorption region R1 and the first and second oxidizing regions R2 and R3 are separated by the separation regions D and the flow path 16. Therefore, in an unnecessary place, deposits are less likely to be generated by the contact between the raw material gas and the oxidizing gas.

The operation of the separation region D in which the separation region forming member 4 of this example is provided, will be described with reference to FIGS. 4 and 5. The height dimension h₂ of the narrow gap between the radial edge portions 42 and the upper surface of the rotary table 2, and the width dimension of the gap between the outer periphery of the rotary table 2 and the inner periphery of the circumferential edge portion 43 are sufficiently smaller than the height dimension h₁ of the buffer space 40. Therefore, the N₂ gas spreads inside the buffer space 40 and then flows outward of the separation region D via the aforementioned gaps.

At this time, each of the aforementioned gaps becomes a resistance against the flow of the N₂ gas, and the internal pressure of the buffer space 40 is higher than the pressure outside the buffer space 40. As a result, due to both the flow of the N₂ gas flowing outward of the separation region D and the pressure difference between the inside and the outside of the buffer space 40, there is presumably formed a state in which the respective processing gases (the raw material gas (ZAC gas) and the oxidizing gas (ozone gas)) supplied to the adsorption region R1 and the first and second oxidizing regions R2 and R3 is less likely to enter other processing regions.

The separation gas nozzle 52 or 55 is inserted into the buffer space 40 along the radial direction of the rotary table 2 and is configured to supply the N₂ gas in the lateral direction (FIG. 3). As described above, in other gas nozzles 51, 53 and 54, the discharge holes 56 are formed in the lower surface of the nozzle body to discharge gases downward. In this case, the gases collide with the surfaces of the rotary table 2 and the wafer W, whereby a gas flow travelling in the lateral direction along these surfaces is formed. Therefore, if the separation gas nozzle having the same configuration as that of other gas nozzles 51, 53 and 54 is disposed inside the buffer space 40, a bypass flow may possibly be generated in which the N₂ gas flows out from the gap between the rotary table 2 and the edge portions 42 and 43 before the N₂ gas sufficiently spreads inside the buffer space 40. Thus, by supplying the N₂ gas in the lateral direction toward the buffer space 40, it is possible to uniformly increase the internal pressure of the buffer space 40.

However, it is not an indispensable requirement to adopt the configuration in which the N₂ gas is supplied in the lateral direction from the separation gas nozzle 52 or 55 inserted in the radial direction. In the case where the action of separating the respective processing regions can be sufficiently obtained by merely providing the buffer space 40, it may be possible to use the separation gas nozzle 52 or 55 having the same configuration as the raw material gas nozzle 51 and the like. In this case, a large number of gas discharge holes may be formed at intervals in one side surface or both side surfaces of a narrow pipe constituting the nozzle body of the separation gas nozzle 52 or 55, thereby suppressing formation of the aforementioned bypass flow which may otherwise be formed when the separation gas collides with the surfaces of the rotary table 2 and the wafer W.

The internal pressure of the buffer space 40 may be adjusted by increasing or decreasing the supply flow rate of the N₂ gas supplied from the separation gas nozzle 52 or 55. The internal pressure of the buffer space 40, which can sufficiently separate the respective processing regions (the adsorption region R1 and the first and second oxidizing regions R2 and R3), varies depending on the processing conditions such the rotation speed of the rotary table 2, the pressure outside the buffer space 40, and the like. It is therefore difficult to unequivocally specify the internal pressure of the buffer space 40. However, as shown in Examples to be described later, the supply flow rate of the N₂ gas necessary for separating the respective processing regions can be grasped in advance by a fluid simulation, an experiment or the like that reflects actual processing conditions.

Returning to the description of the film forming process, the supply of various gases from the raw material gas nozzle 51 and the first and second oxidizing gas nozzles 53 and 54 is stopped when a ZrO film having a desired film thickness is formed on each wafer W by executing the above-described operation, for example, when the rotary table 2 is rotated a predetermined number of times. Then, the rotation of the rotary table 2 is stopped, and the output of the heater 32 is brought into a standby state, whereby the film formation process is terminated. Thereafter, the internal pressure of the vacuum container 11 is adjusted to the state at the time of unloading the wafer W. The gate valve 37 is opened, and the wafer W is taken out in reverse order from when the wafer was loaded thereby completing the film forming process.

The film forming apparatus 1 according to the present embodiment provides the following effects. The separation region forming member 4 provided with the concave portion 41 is disposed in the separation region D for separating the atmospheres of the adsorption region (first processing region) R1 and the first and second oxidizing regions (second processing regions) R2 and R3, and the N₂ gas (separation gas) is supplied into the buffer space 40 formed between the rotary table 2 and the concave portion 41. This makes it possible to effectively separate the respective regions R1 and R2 or R3.

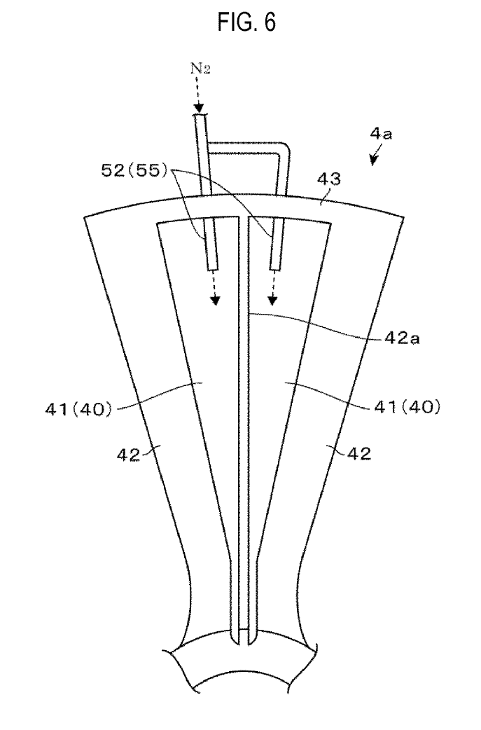

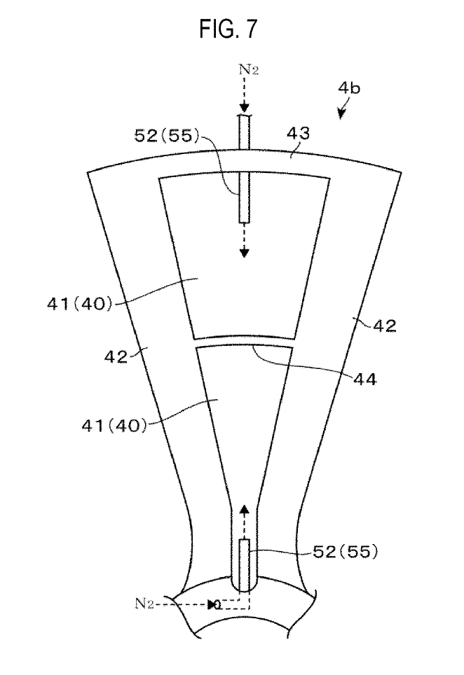

The configuration of the buffer space 40 in each separation region D (the separation region forming member 4) is not limited to the example described with reference to FIG. 3. For example, as in the case of a separation region forming member 4a shown in FIG. 6, a partitioning portion 42a may be provided to divide the concave portion 41 in the radial direction and to form a plurality of buffer spaces 40. The separation gas nozzle 52 or 55 may be inserted into the each buffer space 40. Further, as in the case of a separation region forming member 4b shown in FIG. 7, the concave portion 41 may be circumferentially divided by a partitioning portion 44. FIG. 7 shows an example in which the separation gas nozzle 52 or 55 is inserted from the center side of the rotary table 2 into the buffer space 40 disposed radially inward of the rotary table 2.

Furthermore, it is not essential that the plan-view shape of the separation region forming member 4 and the concave portion 41 is a fan shape. For example, a separation region forming member 4 having a substantially rectangular shape may be provided to cover the region from the peripheral edge side to the center side of the rotary table 2 in a band shape. Further, a concave portion 41 having a rectangular plan-view shape may be formed on the lower surface side of the separation region forming member 4 to define a buffer space 40.

The film formed by using the film forming apparatus 1 of this embodiment is not limited to the ZrO film. For example, the film forming apparatus 1 of this embodiment may be applied to a case where a SiO₂ film is formed by using a dichlorosilane (DCS) gas, a bis(tert-butylamino)silane (BTBAS) gas or the like as a raw material gas (first processing gas) and using an oxygen gas or an ozone gas as an oxidizing gas (second processing gas), or a case where a SiN film is formed by using a DCS gas or a BTBAS gas as a raw material gas and using a nitriding gas (second processing gas) such as an ammonia (NH₃) gas or a nitrous oxide (N₂O) gas instead of an oxidizing gas.

In addition, for example, a plasma forming part provided with an antenna for plasma formation may be provided in the region where the oxidizing region cover 6 is provided, and a plasma forming gas (corresponding to the second processing gas) such as an oxygen gas or an argon gas may be converted into plasma to modify a molecular layer formed by an oxidizing gas, a nitriding gas or the like. In this case, the second oxidizing region R3 becomes a plasma forming region (second processing region) R3. The plasma forming region R3 and the adsorption region R1 are separated by the separation region D using the separation region forming member 4.

Furthermore, for example, three separation region forming members 4 may be disposed inside the vacuum container 11 provided with an adsorption region R1, a reaction region (oxidizing region or nitriding region) R2 and a plasma forming region R3, thereby separating the respective regions R1, R2 and R3 from each other. In this case, one of the regions R1, R2 and R3 adjacent to each other across each separation region D corresponds to a first processing region, and the other corresponds to a second processing region.

### Examples

### Simulation

The member forming the separation region D was changed to simulate a state of occurrence of entry of a ZAC gas into the first oxidizing region R2 from the adsorption region R1.

### A. Simulation Conditions

### Example 1

Simulation was performed for a case where the buffer space 40 is formed using the separation region forming member 4 according to the embodiment described with reference to FIGS. 1 to 5. As the design variables of the separation region forming member 4, the center angle θ is 30 degrees, the height h₁ of the buffer space 40 is 17.5 mm, the height h₂ of the gap between the lower surfaces of the edge portions 42 and the upper surface of the rotary table 2 is 3 mm, and the width dimension w of the edge portions 42 is about 55 mm. As the processing conditions, the internal pressure of the vacuum container 11 is 266 Pa, the supply flow rate of the ZAC gas is 1 slm, the supply flow rate of the N₂ gas is 5 slm, and the rotation speed of the rotary table 2 is 6 rpm.

### Comparative Example 1

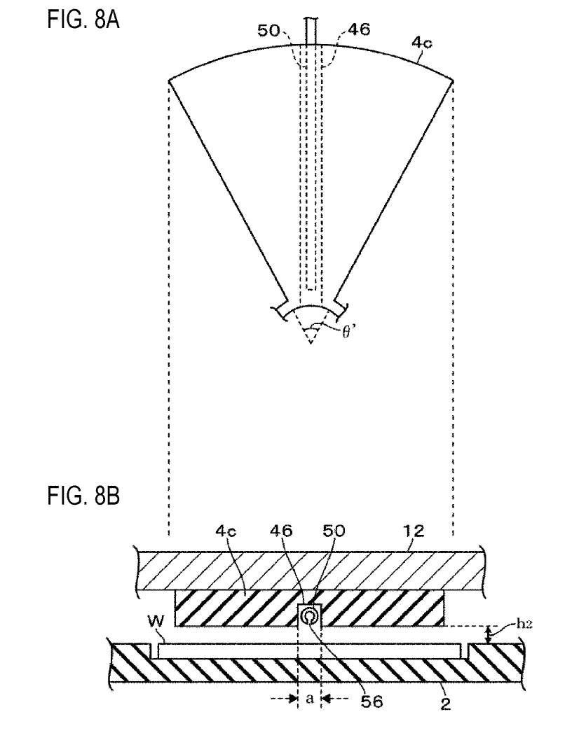

As shown in FIG. 8, simulation was performed under the same conditions as Example 1, except that an N₂ gas is supplied using a separation gas nozzle 50 having a large number of discharge holes 56 formed at intervals along the lower surface of a nozzle body and a groove portion 45 having a width “a” of 20 mm configured to accommodate the separation gas nozzle 50 is formed, and except that a separation region D is formed by using a conventional separation region forming member (convex portion) 4c (having a central angle θ′ of 60 degrees) which is not provided with a concave portion.

### B. Simulation Result

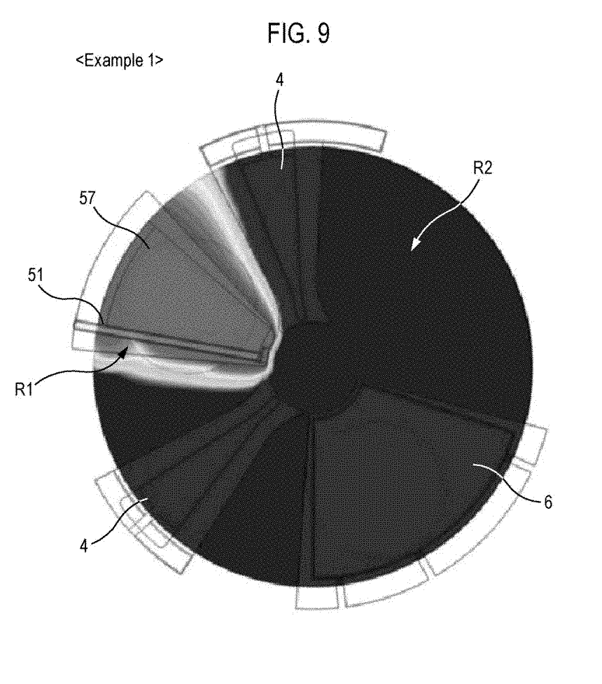

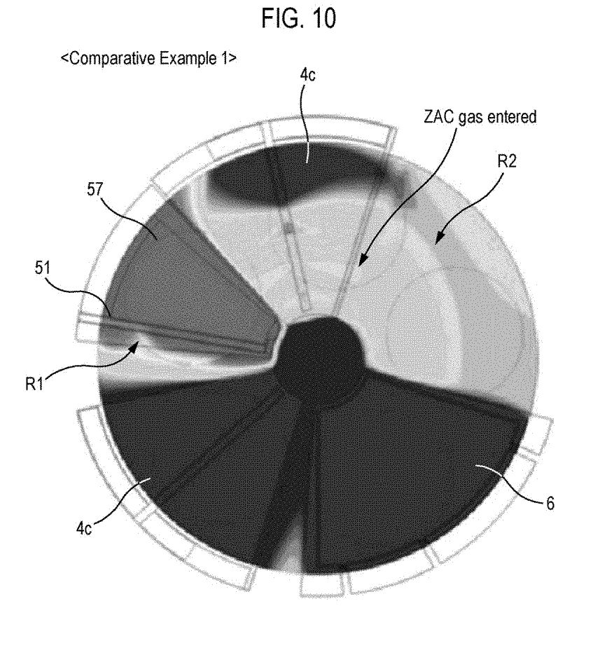

The result of Example 1 is shown in FIG. 9, and the result of Comparative Example 1 is shown in FIG. 10.

According to the result of Example 1 shown in FIG. 9, it was confirmed that the ZAC gas supplied to the adsorption region R1 hardly enters the first oxidizing region R2. On the other hand, in Comparative Example 1 using the conventional separation member forming member 4c, it was confirmed that a portion of the ZAC gas passes through the separation region D and enters the first oxidizing region R2. Accordingly, in order to sufficiently separate the adsorption region R1 from the first oxidizing region R2, it is necessary to increase the supply amount of the N₂ gas.

As compared with the conventional separation region forming member 4c used in Comparative Example 1, the separation region forming member 4 according to the present embodiment has a small center angle θ and a small size. Nevertheless, it was found that the separation region forming member 4 according to the present embodiment can satisfactorily separate the atmospheres of different processing regions R1 and R2 at the upstream and downstream sides of the separation region D.

### Experiment

Separation regions D were formed using the separation region forming members 4 and 4c described in Example 1 and Comparative Example 2, and ZrO films were formed.

### A. Experiment Conditions

### Example 2-1

In order to ascertain an effective adsorption region R1, six wafers W were mounted on the rotary table 2. A ZAC gas was adsorbed for a predetermined time in a state in which the rotary table 2 is stopped. Thereafter, while rotating the rotary table 2, an ozone gas was supplied to the oxidizing region cover 6 only from the second oxidizing gas nozzle 54 for a predetermined period of time to form a ZrO film. The adsorption of the ZAC gas was carried out in two cases by shifting the stop position of the rotary table 2. The film forming conditions are the same as in Example 1 except that the supply flow rate of the ozone gas is 10 slm, the supply flow rate of the N₂ gas is 10 slm, and the reaction temperature is 250 degrees C.

### Example 2-2

In order to ascertain an effective second oxidizing region R3, six wafers W were placed on the same rotary table 2 as used in Example 2-1. A ZAC gas was adsorbed for a predetermined period of time by rotating the rotary table 2. Thereafter, in a state in which the rotary table 2 is stopped, an ozone gas was supplied to the oxidizing region cover 6 only from the second oxidizing gas nozzle 54 for a predetermined period of time to form a ZrO film. The supply of the ozone gas was carried out in two cases by shifting the stop position of the rotary table 2. The film forming conditions are the same as in Example 2-1.

### Comparative Example 2-1

Film formation was performed under the same conditions as in Example 2-1, except that the separation region forming member 4c of Comparative Example 1 is used.

### Comparative Example 2-2

Film formation was performed under the same conditions as in Example 2-2, except that the separation region forming member 4c of Comparative Example 1 is used.

### B. Experiment Results

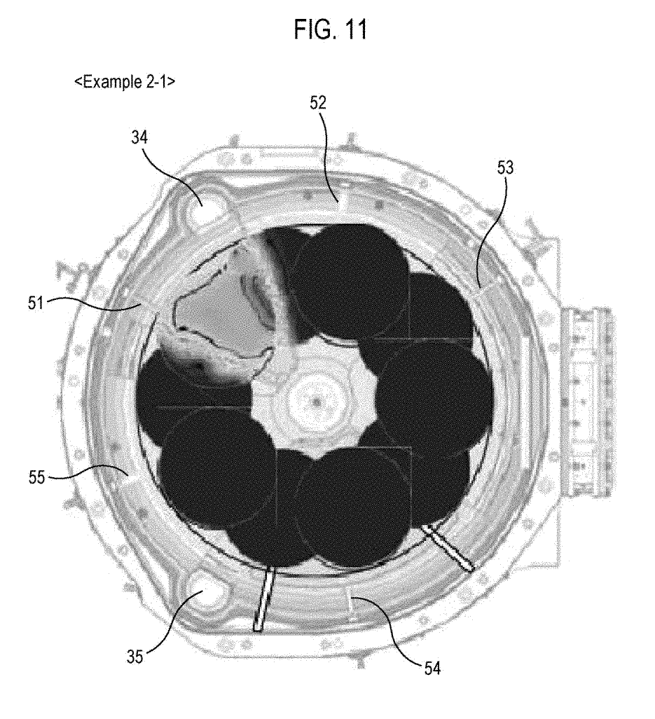

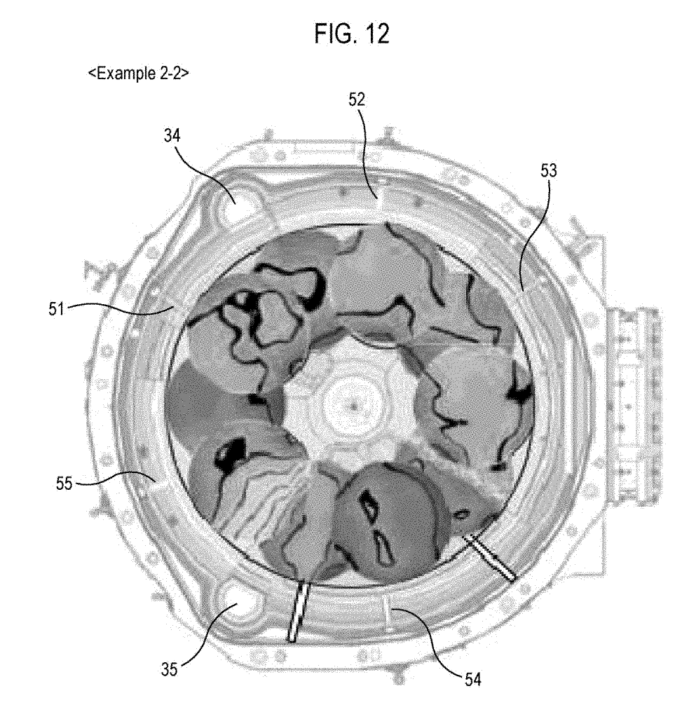

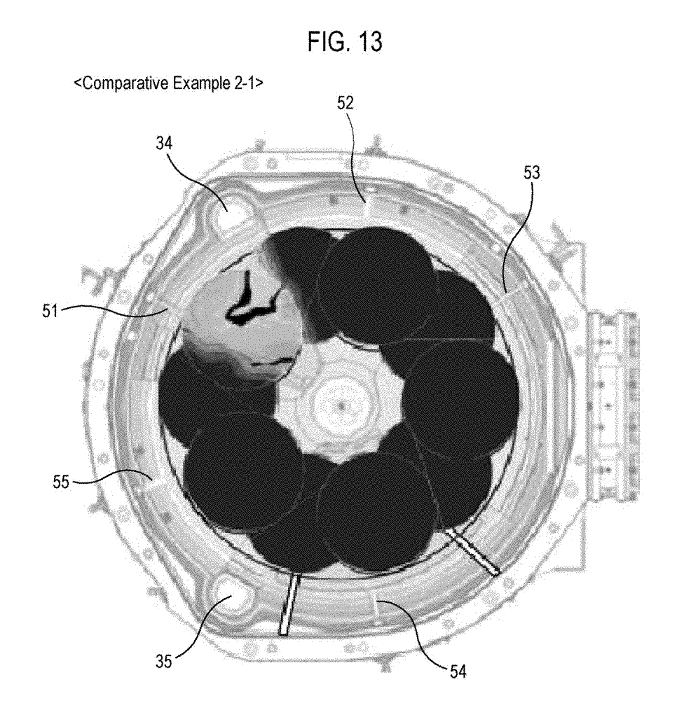

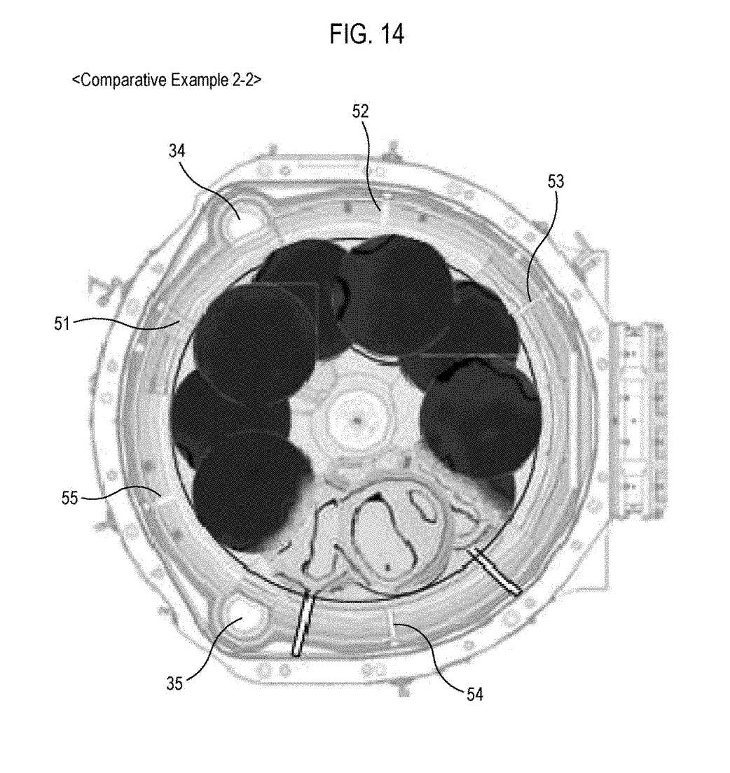

FIGS. 11 and 12 show the film thickness distributions of the ZrO film at the respective stop positions of the wafer W on the rotary table 2 after the film forming processes of Examples 2-1 and 2-2. FIGS. 13 and 14 similarly show the film thickness distributions in Comparative Examples 2-1 and 2-2. In these figures, the film formation results of two cases performed by shifting the stop position are overlappingly indicated.

According to the result of Example 2-1 shown in FIG. 11, even if the supply flow rate of the N₂ gas supplied from the separation gas nozzles 52 and 55 is relatively increased at a level of 10 slm, it is possible to supply the ZAC gas to the adsorption region R1 at a high concentration. On the wafer W disposed in the adsorption region R1, a ZrO film having an average thickness of 6.43 nm was formed.

Further, according to the result of Example 2-2 shown in FIG. 12, it was confirmed that a region (second oxidizing region R3) capable of oxidizing the ZAC gas exists in a wide region where ZAC expands to the downstream side from the region covered with the oxidizing region cover 6. On the wafer W disposed in the second oxidizing region R3, a ZrO film having an average thickness of 1.79 nm was formed.

On the other hand, according to the result of Comparative Example 2-1 shown in FIG. 13, the ZAC gas was diluted due to the influence of the N₂ gas whose supply flow rate is increased in order to enhance the separation effect of the separation region using the separation region forming member 4c. As a result, the average film thickness of the ZrO film of the wafer W disposed in the adsorption region R1 was reduced to 3.46 nm.

In addition, according to the result of Comparative Example 2-2 shown in FIG. 14, as compared with Example 2-2, the range of the second oxidizing region R3 was narrowed due to the influence of the N₂ gas whose supply flow rate is increased. Furthermore, the average film thickness of the ZrO film formed on the wafer W disposed in the second oxidizing region R3 was also reduced to 1.64 nm. According to the results of Examples 2-1 and 2-2 and Comparative Examples 2-1 and 2-2, it was confirmed that the film forming apparatus 1 provided with the separation region D having the buffer space 40 formed therein can form a thick film in a short period of time and exhibits enhanced film formation efficiency.

According to the present disclosure, a separation region forming member having a concave portion is disposed in a separation region for separating atmospheres of first and second processing regions. A separation gas is supplied into a buffer space formed between a rotary table and the concave portion. It is therefore possible to effectively separate the first and second processing regions.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming apparatus for performing a film forming process by mounting a substrate on one surface side of a rotary table provided inside a vacuum container and supplying a processing gas to the substrate while revolving the substrate around a rotation center of the rotary table by rotating the rotary table, comprising:
a first processing gas supply part and a second processing gas supply part provided apart from each other in a rotation direction of the rotary table and configured to supply a first processing gas and a second processing gas to the substrate, respectively; and
a separation region formed between a first processing region and a second processing region to separate an atmosphere of the first processing region to which the first processing gas is supplied and an atmosphere of the second processing region to which the second processing gas is supplied,
wherein the separation region includes:
a separation region forming member including a plurality of edge portions extending in a radial direction from a rotation center to a peripheral edge of the rotary table, the plurality of edge portions being spaced apart from each other in the rotation direction, and configured to form a narrow space between the plurality of edge portions and the rotary table, and a concave portion provided in a region sandwiched between the plurality of edge portions disposed adjacent to each other, the concave portion being opened toward one surface side of the rotary table, and configured to form a buffer space having a larger height dimension than the narrow space between the concave portion and the rotary table; and
a separation gas supply part configured to supply a separation gas into the buffer space.

2. The apparatus of claim 1, wherein the separation region forming member is formed to have a fan shape in a plan view, the plurality of edge portions is provided at both ends of the fan shape, and an angle defined by the plurality of edge portions falls within a range of 20 degrees or more and 60 degrees or less.

3. The apparatus of claim 1, wherein the separation gas supply part includes a separation gas nozzle configured to discharge the separation gas into the buffer space along a radial direction of the rotary table.

4. The apparatus of claim 3, wherein the separation gas nozzle is provided at a position where the separation gas is discharged into the buffer space from the peripheral edge side or the rotation center side of the rotary table.
